(19) United States
(12) Patent Application Publication
(10) Pub. No.: US 2014/0063767 A1
(43) Pub. Date: Mar. 6, 2014

(54) CIRCUIT DEVICE

(71) Applicant: SANYO ELECTRIC CO., LTD., Osaka (JP)

(72) Inventors: Kouichi SAITOU, Gifu (JP); Yoshio OKAYAMA, Shiga (JP); Mayumi NAKASATO, Gifu (JP)

(73) Assignee: SANYO ELECTRIC CO., LTD., Osaka (JP)

(21) Appl. No.: 14/075,847

(22) Filed: Nov. 8, 2013

Related U.S. Application Data
(63) Continuation of application No. PCT/JP2012/006170, filed on Sep. 27, 2012.

(30) Foreign Application Priority Data
Sep. 30, 2011 (JP) 2011-217074

(51) Int. Cl. H05K 1/11

(52) U.S. Cl. CPC H05K 1/111
USPC 361/783

(57) ABSTRACT

A circuit device according to one exemplary embodiment includes a ceramic substrate, a first conductive pattern provided on one face of the ceramic substrate, a second conductive pattern, formed mainly of Cu, which is provided on the other face of the ceramic substrate, and a semiconductor element provided on an island that constitutes the second conductive pattern. An electrode, whose outermost surface is formed mainly of Cu, is provided in the semiconductor element, and the interface between the island and the electrode is directly fixed by solid-phase bonding.

This application is based upon and claims the benefit of priority from the prior Japanese Patent Application No. 2011-217074, filed on Sep. 30, 2011, and International Patent Application No. PCT/JP2012/006170, filed on Sep. 27, 2012, the entire content of each of which is incorporated herein by reference.

### BACKGROUND OF THE INVENTION

1. Field of the Invention

The present disclosure relates to a circuit device where Cu and Cu are bonded together.

2. Description of the Related Art

There are striking changes in the environment associated with the global warming, and activities aiming at a reduction of CO₂ emissions are on the move. As one of such movements toward the reduction of CO₂ emissions, the need to reduce the power consumption is the main issue.

Demand is high for a reduction in the power consumption of refrigerators, laundry machines or the like, for instance. The demand for reduction in the power consumption thereof has affected the circuit devices used to drive such equipment, and it is strongly urged to develop a circuit device that can minimize power loss.

The circuit devices, which may be inverter modules, for instance, are installed in an air conditioner, a refrigerator and so forth.

Through their earnest and diligent research-and-development efforts, the inventors of the present disclosure have come to recognize that the conventional circuit devices still have room for reduction in the power loss.

### SUMMARY OF THE INVENTION

One non-limiting and exemplary embodiment relates to a circuit device. The circuit device includes: a ceramic substrate; a first conductive pattern provided on one face of the ceramic substrate; a second conductive pattern, formed mainly of Cu, which is provided on the other face of the ceramic substrate; and a semiconductor element provided on an island that constitutes the second conductive pattern. An electrode, whose outermost surface is formed mainly of Cu, is provided in the semiconductor element, and an interface between the island and the electrode is directly fixed together by solid-phase bonding.

Another exemplary embodiment relates also to a circuit device. The circuit device includes: a ceramic substrate; a first conductive pattern provided on one face of the ceramic substrate; a second conductive pattern, formed mainly of Cu, which is provided on the other face of the ceramic substrate; and a semiconductor element provided on an island that constitutes the second conductive pattern. An electrode, whose outermost surface is formed mainly of Cu, is provided in the semiconductor element. Crystal grains, formed mainly of Cu, grow in an interface between the island and the electrode in such manner as to lie across the interface therebetween. And the island and the electrode are directly fixed together by solid-phase bonding.

Additional benefits and advantages of the disclosed embodiments will be apparent from the specification and Figures. The benefits and/or advantages may be individually provided by the various embodiments and features of the specification and drawings, and need not all be provided in order to obtain one or more of the same.

These general and specific aspects may be implemented using a system, a method, and a computer program, and any combination of systems, methods, and computer programs.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1A and FIG. 1B are illustrations with which to explain a circuit device according to an embodiment;

FIG. 2 is an illustration with which to explain a circuit device according to an embodiment; and

FIGS. 3A to 3C are illustrations with which to explain a Cu—Cu bonding used in a circuit device according to an embodiment.

### DETAILED DESCRIPTION

The disclosure will now be described by reference to exemplary embodiments. This does not intend to limit the scope of the present disclosure, but to exemplify the disclosure.

The inventors' knowledge underlying the present disclosure will be explained before the exemplary embodiments are explained in detail. The aforementioned conventional circuit device uses a power semiconductor element; since a large current flows there, a large amount of heat is produced by built-in power semiconductor chips and the like. Such heat produced thereby deteriorates the drive capability of the semiconductor element, resulting in much losses. Thus, the following measures are taken to alleviate the problem. That is, for example, the rise in the temperature of the semiconductor element is suppressed by improving the heat radiation, and the on-resistance is kept at as lowest a level as possible. For example, there is a vertical power MOS (Metal-Oxide Semiconductor) where the current flows from the surface of a chip to the back side thereof. And Au is used for a back-side electrode and is provided on the back side of the power MOS. In this example, solders are provided on both an island of leadframe formed of Cu and an island, formed of Cu, which is provided on the module substrate, so that this power MOS is mounted on the module substrate. Sn and Cu, which constitute the solder, form a Cu—Sn alloy and this alloy of Sn and Cu have attracted attention in recent years because the alloy has a high electric resistance. Hence, a material whose electric resistance is much lower than the alloy thereof is needed.

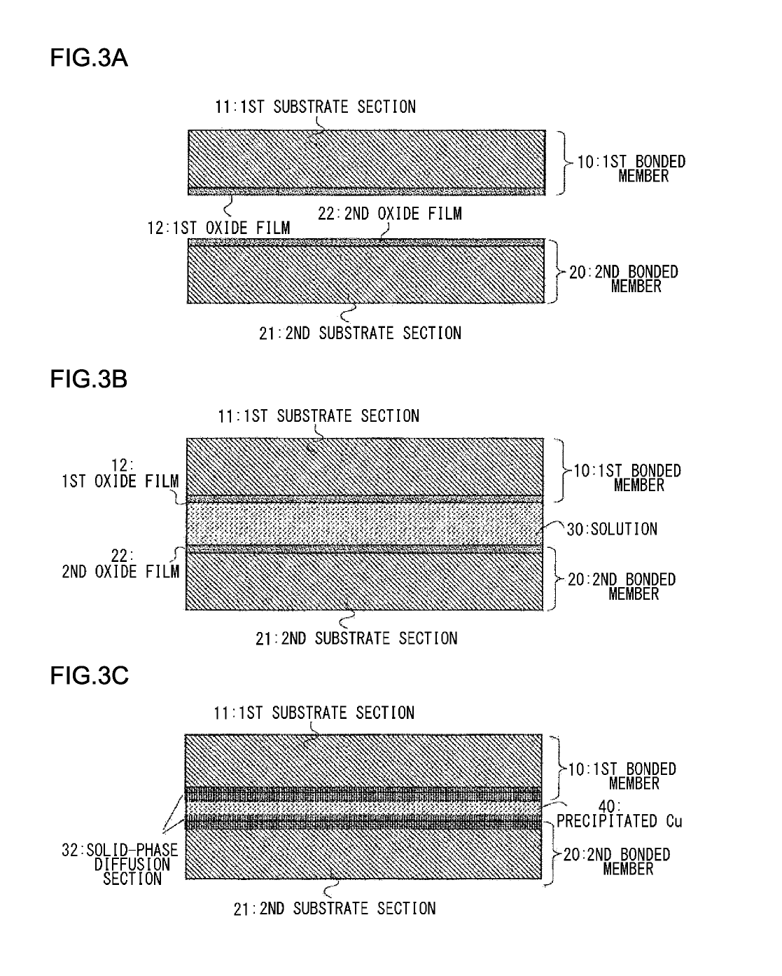

The applicants of the present disclosure had developed a technique by which metals formed mainly of Cu are bonded by a simple method without using the solder. That is, a circuit device according to the present exemplary embodiment at least includes a metal base formed of metallic material, a ceramic substrate provided on the metal base, a first conductive pattern provided on the back side of the ceramic substrate (one face of the ceramic substrate), a second conductive pattern, formed mainly of Cu, which is provided on the surface of the ceramic substrate (the other face of the ceramic substrate), and a semiconductor element provided on an island that constitutes the second conductive pattern. In this circuit device, a back-side electrode (electrode) formed mainly of Cu is provided on an outermost surface of the semiconductor element. Also, an interface between the island and the back-side electrode is directly fixed together using a precipitated copper or a solid-phase diffusion of copper. Also, the first conductive pattern and the metal base are firmly fixed by use of a solder formed mainly of Sn. A description is first given of a principle of technique for bonding together metals formed mainly of Cu and a method therefor, with reference to FIG. 3A to FIG. 3C, followed by a description of the circuit device according to the present embodiment.

As illustrated in FIG. 3A, a first member to be bonded 10 (hereinafter referred to as “first bonded member 10”) and a second member to be bonded 20 (hereinafter referred to as “second bonded member 20”) are first prepared. The first bonded member 10 is comprised of a first substrate section 11, which is formed mainly of Cu, and a first oxide film 12, namely an oxide film of Cu, which is generated in the surface of the first substrate section 11. The second bonded member 20 is comprised of a second substrate section 21, which is formed mainly of Cu, and a second oxide film 22, namely an oxide film of Cu, which is generated in the surface of the second substrate section 21. The expression “A formed mainly of B” or “A mainly composed (or made) of B” as used herein indicates that a base material (i.e., B) dominates over 50% of whole constituents of A. If, for example, “A is formed mainly of Cu”, this means that the Cu content of A is a value exceeding 50%.

The substrate sections are not limited to any particular ones and may be a Cu sheet and another Cu sheet each of which is about several millimeters to several centimeters in thickness, for instance. Also, the substrate sections may be thin metallic wires made of Cu and a Cu pad on a printed circuit board, for instance. Also, the substrate sections may be Cu electrodes on a printed circuit board and Cu electrodes on the back side of a circuit element, for instance. In this manner, the substrate section may be implemented in variety of modes. Also, such a member A made mainly of Cu may be a sheet or foil produced by using a rolling method, a thick film by plating, or a thin film by sputtering, for instance. Although the thicknesses of such sheets, foils, thick films and thin films are not limited to any particular values, the sheet or foil may be about 0.1 mm or greater in thickness, the thick film may be about several tens of micrometers to several hundreds of micrometers in thickness, and the thickness of the thin film may be in units of angstrom, for instance.

The oxide film may be a natural oxide film formed in the air and may be about 10 nm in thickness, for instance. Note that the oxide film may be one deliberately coated with a certain material.

Then, as illustrated in FIG. 3B, a space between the first bonded member 10 and the second bonded member 20 is filled with a solution 30. More specifically, the solution 30 is filled into the space between the first oxide film 12 of Cu and the second oxide film 22 of Cu. The solution 30 may be one that elutes or dissolves oxidized copper. Also, the solution 30 is inert with respect to the substrate sections formed mainly of Cu.

The solution 30 as used herein may be ammonia water (NH₃OH+H₂O), oxalic acid (HOOC—COOH+H₂O), tartaric acid (HOOC—CH(OH)—CH(OH)—COOH+H₂O), lactic acid (CH₃CH(OH)COOH+H₂O) or the like, for instance.

The solution 30 is filled into a space between the first oxide film 12 and the second oxide film 22 so as to form a thin film of 1 μm in thickness, for instance. Here, as for the expression “filling” as used herein, the actual “filling” may be achieved as follows. The solution 30 is first dripped or sprayed onto the surface of one of the two Cu sheets using an atomizer or the like so as to provide the solution 30 on the surface of one Cu sheet. Or alternatively, one Cu sheet is immersed in the solution 30 so as to provide the solution 30 on the surface of one Cu sheet. Then the other Cu sheet is placed on top of the thus formed solution 30. This achieves the filling of the solution 30 into the space between one Cu sheet and the other Cu sheet.

In this manner, filling the space between the first bonded member 10 and the second bonded member 20 with the solution 30 causes the oxidized copper in the first oxide film 12 and the second oxide film 22 to solve out into the solution 30. Thereby, the first oxide film 12 and the second oxide film 22 disappear. As a result, the first bonded member 10 and the second bonded member 20 have changed such that the surface of each substrate section, namely Cu, is exposed.

If the solution 30 is ammonia water, a complex of copper is formed by ammonia ions and a copper ion. It is considered that the copper complex exists as a heat decomposable tetraamine complex ion expressed by [Cu(NH₃)₄]²⁺. Since ammonia water is inert with respect to Cu, the copper constituting the substrate sections does not react with ammonia water and remains there.

Then, the solution 30 is heated at a temperature of about 200 to 300° C. while the first bonded member 10 and the second bonded member 20 are pressurized. Heating the solution 30 evaporates water and causes tetraamine copper complex ion to be pyrolyzed with the result that the ammonia component evaporates.

Through these processes, the ratio of Cu in the solution 30 increases gradually. And the pressurizing applied by a press machine results in a gradual decrease in the distance between the outermost surface of the first bonded member 10 and the outermost surface of the second bonded member 20, so that the first bonded member 10 and the second bonded member 20 are gradually getting closer to each other.

Furthermore, the components other than copper in the solution 30, namely the components other than the metal formed mainly of copper, is removed. As the removal of the components other than the metal formed mainly of copper has been completed, the outermost surface of the first bonded member 10 and the outermost surface of the second bonded member 20 are joined together.

As illustrated in FIG. 3C, two layers of solid-phase diffusion sections 32 (solid-phase diffusion layers) are produced between the first substrate section 11 and the second substrate section 21. That is, crystal grains grow in such a manner as to lie across the interface between the first substrate section 11 and the second substrate section 21. A precipitated copper 40 is disposed between the two solid-phase diffusion sections 32. In this manner, the pressurizing is terminated after the first bonded member 10 and the second bonded member 20 are bonded together

Through the processes as described above, the bonding by intermetallic solid-phase diffusion is completed.

It is to be noted here that the first substrate section 11 and the second substrate section 21 may undergo surface polishing. For example, the first substrate section 11 and the second substrate section 21 are polished using a diamond paste in which diamond powders of 3 μm in diameter are mixed. The weighting applied at the time of polishing is 5.8 MPa, for instance. Excellent results have been obtained in the experiments when the holding time of weighting is in a range of 5 minutes to 60 minutes. Recent reports show, however, that the bonding can be done even though the holding time thereof is several seconds only.

Though the bonding temperature for ammonia water of about 3% is about 200 to 300° C., the bonding temperature for tartaric acid is about 110 to 200° C.

Assume, on the other hand, that the solution 30 used is oxalic acid, dicarboxylic acid, tartaric acid, citric acid, or lactic acid. Then, the chelation by oxycarbonic acid dissolves oxidized copper. Thus, the Cu—Cu bonding can be more effectively formed than when ammonia water is used. Besides, the bonding temperature can be brought down to about 110 to 200° C. or it can be brought down to about 125° C. at a suitable point. Also, the metal to be bonded is not limited to a metal formed mainly of copper and, for example, it may be a metal made mainly of gold or a metal made mainly of aluminum.

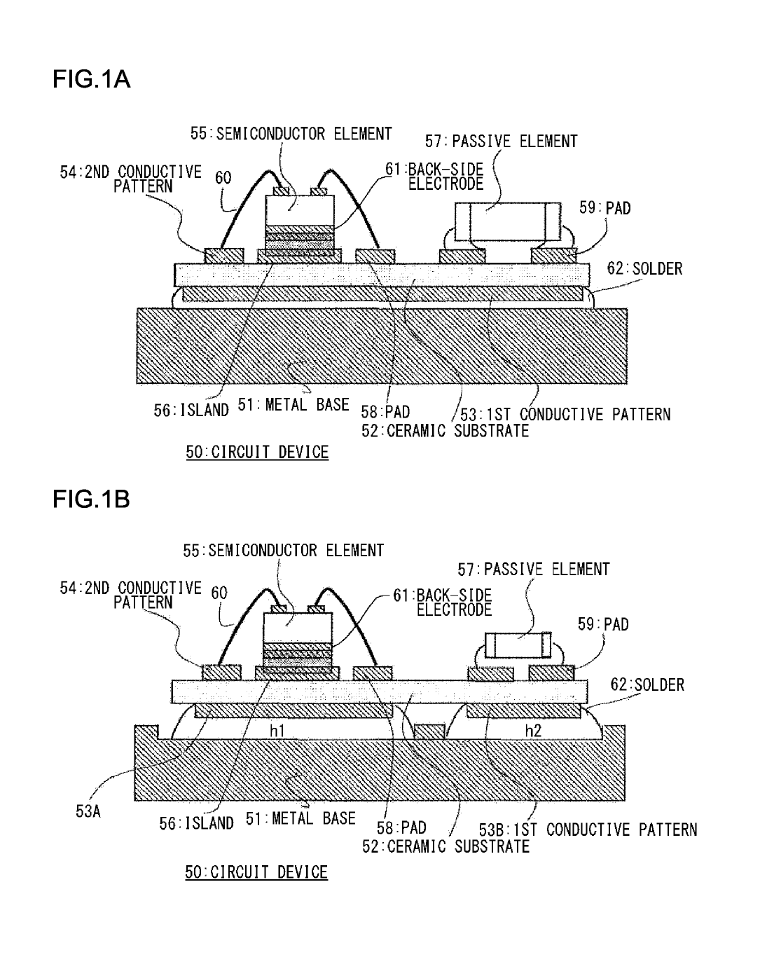

A description is now given of a circuit device 50 with reference to FIG. 1A. The circuit device 50 is a semiconductor device if a semiconductor element only is mounted; the circuit device 50 is a hybrid integrated circuit (IC) device if it is configured by a semiconductor element and a passive element. The circuit device 50 is also called a power module if the semiconductor element is a large-current semiconductor element. Moreover, the circuit device 50 is an optical semiconductor device or an optical module if a light-emitting diode (LED) is implemented as the semiconductor element. Also, the components of the circuit device 50 may be sealed with a resin by transfer molding or may be can-encapsulated with a metal. Further, the circuit device 50 may be a module, as shown in FIG. 1A, with no sealing measures. Here, all of these described above are generically called “circuit device”.

The circuit device 50 is first provided with a metal base 51 that functions as a heatsink. The metal base 51 as used herein is formed of Cu or metal formed mainly of Cu. As will be discussed later, the metal constituting the metal base 51 may be Al. Since the voltage endurance characteristics or high frequency is needed, the circuit device 50 includes a ceramic substrate 52. The material used for the ceramic substrate 52 may be aluminum oxide (Al₂O₃), aluminum nitride (AlN), silicon nitride (Si₃N₄), or the like, for instance.

Conductive patterns made of Cu or metal formed mainly of Cu are provided in the surface (the other face) of the ceramic substrate 52 and the rear surface (one face) thereof. A first conductive pattern 53 provided on a rear surface side of the ceramic substrate 52 is practically formed on the almost entire rear surface of the ceramic substrate 52. Or alternatively, the first conductive pattern 53 is formed on the entire rear surface of the ceramic substrate 52 such that the edge of the first conductive pattern 53 is located slightly inward from the outer circumference of the ceramic substrate 52. The first conductive pattern 53 is connected to the metal base 51 by a solder 62.

A second conductive pattern 54 provided on a surface side of the ceramic substrate 52 is formed of the same material as that constituting the first conductive pattern 53. In the present exemplary embodiment, the second conductive pattern 54 is formed in a shape of circuit pattern, and has an island 56, on which a semiconductor element 55 is mounted, and pads 58 and 59, which are electrically connected to the semiconductor element 55 and a passive element 57, respectively. Further, the second conductive pattern 54 may have wirings that are formed integrally with the pads 58 and 59 or the island 56 or disposed in an island-like shape.

In the present exemplary embodiment, the semiconductor element 55 is a semiconductor element for use in a large-current device and is a vertical semiconductor element formed of a semiconductor material such as Si, SiC, GaN. A bonding pad in the surface of the semiconductor element 55 and the pad 58 on the ceramic substrate 52 are connected by a thin metallic wire 60. Since, in this large-current semiconductor element 55, the current flows out of or inside a chip's backside, a back-side electrode 61 (electrode) is formed on the chip's backside. The outermost surface of the back-side electrode 61 is made of Cu. For example, the back-side electrode 61 is formed such that Al, Ti, Ni, Ag, and Cu are stacked in this order starting from the back side of Si chip. Cu is generally formed by plating but sputtering may be used to form a Cu film. The back-side electrode 61 is similarly formed when the semiconductor element 55 is SiC or GaN. The back-side electrode 61 of the semiconductor element 55 and the island 56 of the ceramic substrate 52 are electrically and physically bonded to each other by the Cu—Cu bonding employed in the present exemplary embodiment.

The pad 59 is used to electrically connect the passive elements 57. Here, the passive elements 57 are a chip resistor, a chip capacitor and so forth.

In the present exemplary embodiment, the solution 30 as explained in conjunction with FIG. 3A to FIG. 3C is provided in the island 56 of the ceramic substrate 52. A collet mounted on a chip adsorption device (chip bonder) adsorbs the semiconductor element 55 on its surface and, in this state, places the back-side electrode 61 on the island 56. At the same time, a table of the bonder is heated and then the ceramic substrate 52 placed on the table is heated in its entirety. Thus pressurizing the semiconductor element 55 placed on the ceramic substrate 52 using the aforementioned collet can achieve the Cu—Cu bonding between the chip's backside and the island surface.

Since the Cu—Cu bonding is achieved by the solid-phase diffusion, the resistance value between the back-side electrode 61 and the island 56 is smaller than that of the solder. As a result, the loss caused by the circuit device 50 can be reduced. Further, the thermal resistance between the back-side electrode 61 and the island 56 is also reduced, and the heat generated by the semiconductor element 55 can be promptly conducted to the ceramic substrate 52 and/or metal base 51.

Also, the solder 62 having a low melting point is used to fix the metal base 51 and the first conductive pattern 53. For example, a solder made of Sn—Ag—Cu at 230° C. is used. This solder 62 can mitigate the stress caused by the difference in thermal expansion coefficients between the ceramic substrate 52 and the metal base 51.

Note here that the thermal expansion coefficient of the ceramic substrate 52 and that of a semiconductor chip are close to each other. Accordingly, the stress acting on a Cu—Cu joint part due to the difference in thermal expansion coefficients between the ceramic substrate 52 and the semiconductor chip is smaller than the stress acting on a joint part of the metal base 51 and the ceramic substrate 52. The semiconductor chip is markedly smaller than the ceramic substrate 52 in size. Thus the stress occurring between the semiconductor chip and the ceramic substrate 52 is even smaller. Thus, the demand for the stress relaxation through the insertion of a thermal stress relaxation layer into between the semiconductor chip and the ceramic substrate 52 is not high. Also, a portion where a thermal stress, which is greater than that acting on the Cu—Cu joint part, acts on can mitigate the stress by using the soft solder 62.

The thermal resistance for the Cu—Cu bonding formed by the solid-phase diffusion is smaller than the thermal resistance for the solder bonding. Thus the heat generated by the semiconductor chip easily propagates to the ceramic substrate 52 located beneath the semiconductor chip. Also, the thermal resistance of the solder 62 is higher than the thermal resistance for the Cu—Cu bonding. However, a joint surface between the solder 62 and the ceramic substrate 52 and a joint surface between the solder 62 and the metal base 51 are each larger than and is made wider than a Cu—Cu joint surface. Thus, a large amount of heat is more likely to conduct to the metal base 51 from a semiconductor element 55 side. Hence, the highly heat-radiant circuit device 50 with less stress applied can be realized in terms of a device as a whole.

Although a description has been given hereinabove of the intermetallic solid-phase diffusion where the solution 30 is used for the Cu—Cu bonding, this should not be considered as limiting. For example, the Cu—Cu bonding may be obtained by performing a solid layer bonding such that, in the pressurized or non-pressurized state, the solid-phase interfaces are bonded together without melting the base material and without using a liquid-phase metallic material (e.g., brazing material) for a bonded interface. For example, the solid layer bonding without the solid-phase diffusion may be obtained by employing a method where the surfaces of bonded members, which have been activated, are bonded together.

The metal base 51 may be provided in such a manner as to surround the pad 58 as illustrated in FIG. 1B, or may be provided in a larger size than that of FIG. 1B. In the example shown in FIG. 1B, the metal base 51 is Cu and therefore the flow of the solder 62 is prevented from flowing out of the metal base 51 and therefore the flexibility of the solder is achieved more efficiently. The structure of a circuit device 50 shown in FIG. 1B is identical to the structure thereof shown in FIG. 1A excluding the components disposed below the ceramic substrate 52 and therefore the repeated description thereof is omitted here.

A conductive pattern 53A is provided in the rear surface of the ceramic substrate 52 and at least directly below the semiconductor chip. The size of the conductive pattern 53A is practically the same as or greater than that of the island 56. Also, the conductive pattern 53A is provided in the same position as seen from a stacking direction of the metal base 51 and the ceramic substrate 52 (in the position that overlaps with the island 56). In the circuit device 50 shown in FIG. 1B, the conductive pattern 53A is provided in the same position as an entire region, where the pad 58 and the island 56 are provided, as seen from the stacking direction thereof (in the position that overlaps with said region). In other words, the area of the conductive pattern 53A provided in the position corresponding to the position of the semiconductor element 55 is larger than the adhesion area of Cu and Cu in the back-side electrode 61 and the island 56 and is smaller than an underside size of the ceramic substrate 52. Here, said underside size of the ceramic substrate 52 is the size of a partial surface of the ceramic substrate 52 where the conductive pattern 53A is provided in the position corresponding to the position of the semiconductor element 55. Below the passive element 57 (chip element), a first conductive pattern 53B, whose size is almost identical to that of the passive element 57, is also provided in the same position as seen from the stacking direction thereof.

Also, the metal base 51 has a plurality of recesses h1, h2, . . . corresponding to the above-described conductive patterns 53A and 53B, and the solders 62 are provided in the respective recesses. Then the conductive patterns 53A and 53B are firmly fixed to the metal base 51 through the medium of the solders 62 provided in the recesses.

The structure employed in the present exemplary embodiment can suppress the flow of the solders 62 by provision of the recesses and can ensure the thickness for the solders 62 depending on the depths of the recesses. As a result, the stress occurring between the ceramic substrate 52 and the metal base 51 can be more mitigated than in the circuit device 50 described conjunction with FIG. 1A.

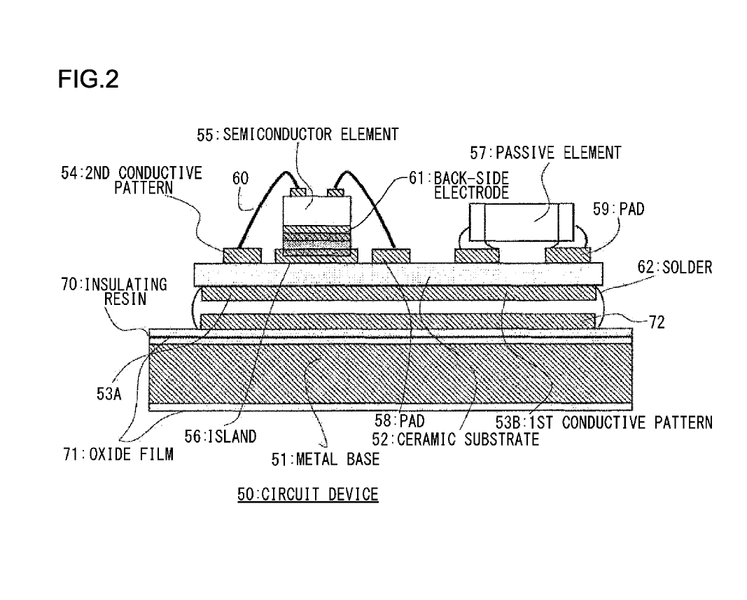

A description is next given of a case where Al is used for the metal base 51 with reference to FIG. 2. Since it is difficult to form a film of Cu directly on top of Al, an insulating resin 70 is used in the present exemplary embodiment. A metal base 51 having oxide films 71 provided on both the surface and the back side of the metal base 51 is prepared. The oxide films 71 are produced by anodically oxidizing the surface and the back side of the metal base 51. Then a Cu foil sheet where the insulating resin 70 has been formed is pasted onto the metal base 51, and the thus formed Cu foil sheet is etched, thereby forming a third conductive pattern 72. Note that the insulating resin 70 shows a larger thermal resistance than the solder. Thus, for example, a filler may be mixed into the resin. The third conductive pattern 72, which is now formed on the metal base 51 made of an Al substrate, may be of the same shape as either that of the first conductive pattern 53 shown in FIG. 1A or that of the first conductive patterns 53A and 53B shown in FIG. 1B. Note that the oxide films 71 may not be provided at all, for example.

Al is slightly inferior than Cu in terms of the heat radiation but the weight of Al is much lighter than Cu. Thus the metal base 51 made of Al is more suitable to a case, where the lightweight properties are necessary, such as a case where the circuit device is installed in a vehicle or the like.

The circuit device 50 described in conjunction with FIG. 2 is configured the same way as the circuit device 50 described in conjunction with FIG. 1A except that the metal base 51 to the third conductive pattern 72 of FIG. 2. That is, the structure of the metal base 51 in FIG. 2 differs from that in FIG. 1A, and the third conductive pattern 72 is added anew in FIG. 2 component-wise. Thus the repeated description of components in FIG. 2 identical to those of FIG. 1A is omitted here.

What is claimed is:

1. A circuit device comprising:
a ceramic substrate;
a first conductive pattern provided on one face of the ceramic substrate;
a second conductive pattern, formed mainly of Cu, which is provided on the other face of the ceramic substrate; and
a semiconductor element provided on an island that constitutes the second conductive pattern,
wherein an electrode, whose outermost surface is formed mainly of Cu, is provided in the semiconductor element, and an interface between the island and the electrode is directly fixed together by solid-phase bonding.

2. A circuit device comprising:
a ceramic substrate;
a first conductive pattern provided on one face of the ceramic substrate;
a second conductive pattern, formed mainly of Cu, which is provided on the other face of the ceramic substrate; and
a semiconductor element provided on an island that constitutes the second conductive pattern,
wherein an electrode, whose outermost surface is formed mainly of Cu, is provided in the semiconductor element,
crystal grains, formed mainly of Cu, grow in an interface between the island and the electrode in such manner as to lie across the interface therebetween, and
the island and the electrode are directly fixed together by solid-phase bonding.

3. A circuit device according to claim 1, wherein solid-phase diffusion sections, which have grown inside a surface of the electrode, and/or solid-phase diffusion sections, which have grown inside a surface of the island, are provided in the interface therebetween.

4. A circuit device according to claim 1, further comprising a metal base formed of metallic material,
wherein the ceramic substrate is provided on the metal base, and
wherein the first conductive pattern and the metal base are fixed by a solder.

5. A circuit device according to claim 4, wherein the metal base is formed mainly of Cu or Al.

6. A circuit device according to claim 4, wherein the metal base has a recess, and
wherein the first conductive pattern is fixed to the metal base by the solder provided in the recess.

7. A circuit device according to claim 1, wherein an area of the first conductive pattern provided in a position corresponding to a position of the semiconductor element is larger than an adhesion area of Cu and Cu in the electrode and the island, respectively, and is smaller than a surface size of the ceramic substrate where the first conductive pattern is provided in the position corresponding to the position of the semiconductor element.
